(19) United States
(12) Patent Application Publication
(10) Pub. No.: US 2025/0317109 A1
(43) Pub. Date: Oct. 9, 2025

(54) RECEIVING CIRCUIT AND CONTROL METHOD THEREOF

(71) Applicant: Winbond Electronics Corp., Taichung City (TW)

(72) Inventor: Takahiko SATO, Yokohama (JP)

(73) Assignee: Winbond Electronics Corp., Taichung City (TW)

(21) Appl. No.: 19/098,400

(22) Filed: Apr. 2, 2025

(30) Foreign Application Priority Data
Apr. 9, 2024 (JP) 2024-062685

(51) Int. Cl. H03F 3/19

(52) U.S. Cl. CPC H03F 3/19

(57) ABSTRACT

A receiving circuit is provided. The receiving circuit includes an amplifier and a control unit. The receiving circuit has a plurality of input terminals and an output terminal. The amplifier is configured to receive an input signal through one of the plurality of input terminals and generate an output signal at the output terminal by amplifying the input signal. The control unit is configured to receive the output signal and provide a feedback resistance based on the input signal. The feedback resistance provided by the control unit when an amplitude of the input signal is greater than or equal to a specific value is smaller than the feedback resistance provided by the control unit when the amplitude of the input signal is less than the specific value.

### CROSS REFERENCE TO RELATED APPLICATIONS

This application claims priority of Japan Patent Application No. 2024-062685, filed on Apr. 9, 2024, the entirety of which is incorporated by reference herein.

### BACKGROUND OF THE INVENTION

### Field of the Invention

The present invention relates to a receiving circuit, and in particular, it relates to a receiving circuit for high precision or high-speed applications and control method thereof.

### Description of the Related Art

In a semiconductor memory device (e.g., Dynamic Random Access Memory (DRAM), etc.), it is well known that a receiving circuit includes an amplifier. An externally input signal can be amplified by the amplifier (e.g., Japan Patent Application No. 2001-103098). In such a receiving circuit, the larger the amplitude of the input signal is, the larger the amplitude of the output signal from the amplifier is. However, in order to increase the speed of signal transmission between the semiconductor memory device and other devices, the pulse width of the input signal is shortened, such that the receiving circuit may have difficulty in appropriately detecting the input signal with the larger amplitude (e.g., the logic level (high level or low level)).

### BRIEF SUMMARY OF THE INVENTION

The present invention considers the above problems and aims to provide a receiving circuit capable of appropriately detecting input signals and control method thereof.

In order to solve the above problems, a receiving circuit is provided. The receiving circuit includes an amplifier and a control unit. The receiving circuit has a plurality of input terminals and an output terminal. The amplifier is configured to receive an input signal through one of the plurality of input terminals and generate an output signal at the output terminal by amplifying the input signal. The control unit is configured to receive the output signal and provide a feedback resistance based on the input signal. The feedback resistance provided by the control unit when an amplitude of the input signal is greater than or equal to a specific value is smaller than the feedback resistance provided by the control unit when the amplitude of the input signal is less than the specific value.

According to an embodiment of the present invention, when the amplitude of the input signal is greater than or equal to the specific value and input to the amplifier, an amplitude of the output signal of the amplifier is reduced, and the receiving circuit can operate with the reduced amplitude of the output signal. Therefore, the receiving circuit can appropriately detect a logic level of the input signal even when the amplitude of the input signal is large and a pulse width of the input signal is shortened.

In addition, a control method of the receiving circuit is provided. The control method includes receiving and amplifying an input signal by an amplifier to generate an output signal and providing a feedback resistance by a control unit based on the input signal. The feedback resistance provided by the control unit when an amplitude of the input signal is greater than or equal to a specific value is smaller than the feedback resistance provided by the control unit when the amplitude of the input signal is less than the specific value.

According to the receiving circuit and the control method thereof of the present invention, the input signal can be detected appropriately even if the signal transmission speed is increased, and it can be applied to high-precision or high-speed applications.

### BRIEF DESCRIPTION OF THE DRAWINGS

FIG. 1 shows an example of a configuration of a receiving circuit according to an embodiment of the present invention.

FIG. 2A shows the time variation of signals in the receiving circuit according to a comparison example.

FIG. 2B shows the time variation of signals in the receiving circuit according to an embodiment of the present invention.

FIG. 3 shows an example of the configuration of a receiving circuit of a first alternative embodiment of the present invention.

FIG. 4 shows an example of the configuration of a receiving circuit of a second alternative embodiment of the present invention.

FIG. 5 shows an example of the configuration of a receiving circuit of a third alternative embodiment of the present invention.

### DETAILED DESCRIPTION OF THE INVENTION

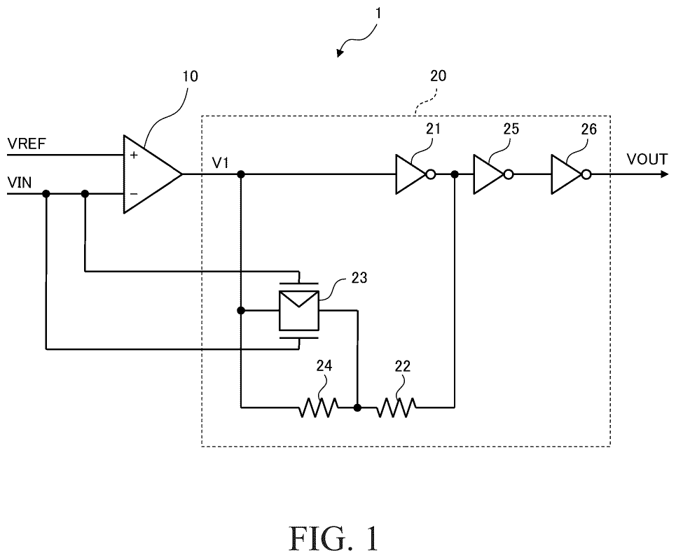

FIG. 1 is a block diagram showing a configuration of a receiving circuit 1 according to an embodiment of the present invention. The receiving circuit 1 of this embodiment may be disposed in a semiconductor memory device (e.g., DRAM such as Double-Data-Rate Fourth Synchronous Dynamic Random Access Memory (DDR4 SDRAM)) and is configured to receive signals input to the semiconductor memory device from an external device. In the embodiment, the receiving circuit 1 includes an amplifier 10 and a control unit 20. For simplicity of illustration, other known components of the semiconductor memory device (e.g., memory cell array, power circuit, command decoder, clock generator, etc.) are not shown herein.

In the embodiment, the amplifier 10 may be a differential amplifier in which a first input terminal (the “−” terminal) receives an input signal VIN and a second input terminal (the “+” terminal) receives a specific reference signal VREF. Therefore, the difference between the voltage of the input signal VIN and the voltage of the reference signal VREF can be amplified (inversely amplified in this embodiment) in the amplifier 10, and common mode noise can be easily removed. Further, the receiving circuit 1 is configured to determine a logic value of the input signal VIN as “1” when the voltage of the input signal VIN is greater than or equal to the voltage of the reference signal VREF, and to determine a logic value of the input signal VIN as “0” when the voltage of the input signal VIN is lower than the voltage of the reference signal VREF. In addition, the difference between the voltage of the input signal VIN and the voltage of the reference signal VREF is amplified by the amplifier 10 (inversely amplified in this embodiment), and the amplified signal is output as the output signal V1. Further, if the semiconductor memory device complies with the DDR4 SDRAM specification, the voltage of the reference signal VREF can be half of the input/output voltage (I/O voltage) VDDQ (i.e., VDDQ/2). Furthermore, the input signal VIN can be an address signal or a command signal from external.

In the embodiment, the control unit 20 is configured to adjust the amplitude of the output signal V1 of the amplifier 10 to reduce it when the amplitude of the input signal VIN is greater than or equal to a specific value.

In addition, the control unit 20 can also make the amplitude of the output signal V1 of the amplifier 10 smaller by increasing the amount of reduction in the amplitude of the output signal V1 of the amplifier 10 when the amplitude of the input signal VIN is greater than or equal to the specific value. Therefore, even if the amplitude of the input signal VIN is greater than or equal to the specific value, the amplitude of the output signal V1 of the amplifier 10 can be easily reduced by increasing the amount of reduction of the amplitude of the output signal V1 of the amplifier 10.

In addition, the control unit 20 may increase the amplitude of a feedback signal applied to the output signal V1 of the amplifier 10 when the amplitude of the input signal VIN is greater than or equal to the specific value. The feedback signal is an inverted signal of the output signal V1, such that the amplitude of the output signal V1 of the amplifier 10 becomes smaller. Therefore, even if the amplitude of the input signal VIN is greater than or equal to the specific value, the amplitude of the output signal V1 of the amplifier 10 can be easily reduced according to the increase in the amplitude of the feedback signal.

In the embodiment, the control unit 20 includes an inverter circuit 21, a first resistor portion 22, a first switch unit 23, a second resistor portion 24, and multiple (the embodiment is two) other inverter circuits 25 and 26.

The inverter circuit 21 is configured to receive the output signal V1 of the amplifier 10. In addition, one end of the first resistor portion 22 is connected to the output of the inverter circuit 21, and the other end of the first resistor portion 22 is connected to the first switch unit 23 and the second resistor portion 24.

One end of the first switch unit 23 is connected to the other end of the first resistor portion 22, and the other end of the first switch unit 23 is connected to the output of the amplifier 10. In addition, the first switch unit 23 is configured to be turned on (activated or closed) when the amplitude of the input signal VIN is greater than or equal to the specific value. In the embodiment, the first switch unit 23 is configured to include a transfer transistor, and gate terminals of the P-channel type Metal-Oxide-Semiconductor Field Effect Transistor (MOSFET) and the N-channel type MOSFET of the transfer transistor receive the input signal VIN. Further, in the embodiment, the N-channel type MOSFET of the transfer transistor is turned on when the amplitude of the input signal VIN with the logic value of “1” (high side) is greater than or equal to the specific value, and the P-channel type MOSFET of the transfer transistor is turned on when the amplitude of the input signal VIN with the logic value of “0” (low side) is greater than or equal to the specific value. Therefore, the first switch unit 23 is turned on when the amplitude of the input signal VIN is greater than or equal to the specific value regardless of whether the logic value of the input signal VIN is “1” or “0”. Furthermore, the first switch unit 23 may be formed by other circuits other than the transfer transistor.

The second resistor portion 24 is connected in parallel with the first switch unit 23 between the other end of the first resistor portion 22 and the output of the amplifier 10. Specifically, one end of the second resistor portion 24 is connected to the other end of the first resistor portion 22, and the other end of the second resistor portion 24 is connected to the output of the amplifier 10.

In addition, the input terminal of the other inverter circuit 25 is connected to the output terminal of the inverter circuit 21. Further, the input terminal of the other inverter circuit 26 is connected to the output terminal of the other inverter circuit 25. Then, the signal from the other inverter circuit 25 is logically inverted by the other inverter circuit 26, and the logically inverted signal is output as an output signal VOUT of the receiving circuit 1. In the embodiment, the amplitude of the output waveform can be shaped to a specific level (e.g., VDDQ/VSSQ, etc.) by the other inverter circuits 25 and 26.

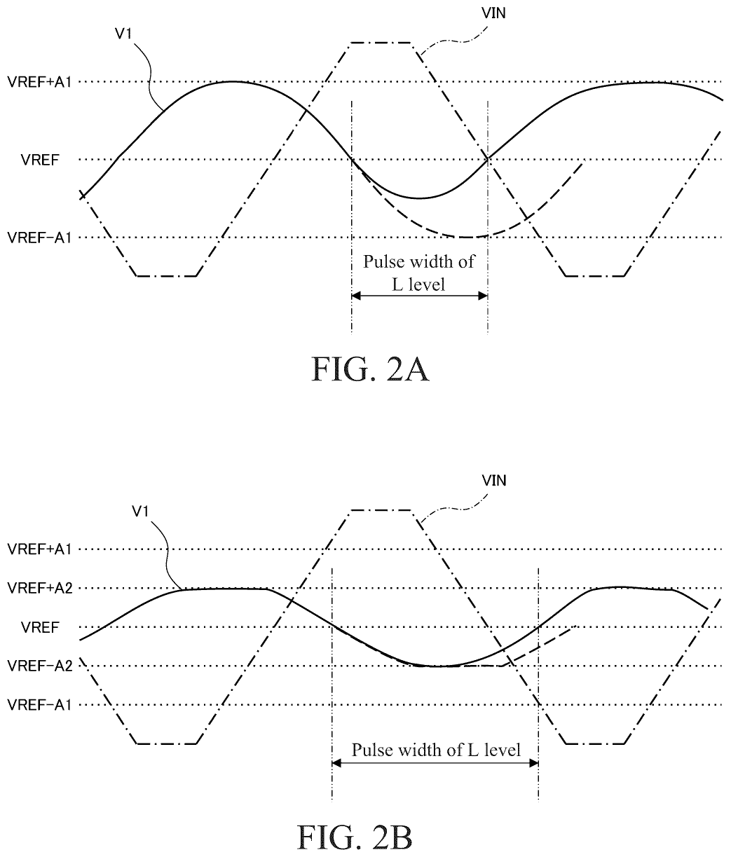

Referring to FIG. 2, FIG. 2 shows an example of the amplitude of the output signal V1 of the receiving circuit 1 becomes smaller according to an embodiment in the present invention. The time graph of FIG. 2A shows a comparison example of the change in time of the input signal relative to the output signal in a conventional receiving circuit. The time graph of FIG. 2B shows the change in time of the input signal relative to the output signal in the receiving circuit 1 in the embodiment. In FIG. 2A, the receiving circuit of the comparison example is similar to the receiving circuit 1, but the control unit does not have the first switch unit 23 and the second resistor portion 24 of the embodiment.

In the receiving circuit of the comparison example, after the amplifier 10 receives the input signal VIN and the reference signal VREF, the difference between the voltage of the input signal VIN and the voltage of the reference signal VREF is amplified by the amplifier 10, and then the amplified signal is output as the output signal V1. The inverter circuit 21 generates a feedback signal by logically inverting the output signal V1, and the feedback signal is feedback to the output signal V1 through the first resistor portion 22. In this case, the output signal V1 of the comparison example is shown in FIG. 2A as a waveform having a maximum amplitude A1 (0<A1) based on the voltage of the reference signal VREF. However, when the pulse width of the input signal VIN (the pulse width of the input signal VIN at the high level shown in FIG. 2A) becomes shorter, a state inversion may occur in the voltage of the output signal V1 before the voltage of the output signal V1 reaches the saturation voltage (VREF-A1 shown in FIG. 2A). In this case, since the pulse width of the low level (L level) of the output signal V1 becomes shorter, the high level of the input signal VIN in the receiving circuit may become difficult to detect.

On the other hand, in the receiving circuit 1 of the embodiment, the first switch unit 23 is turned off (deactivated or opened) when the amplitude of the input signal VIN is less than the specific value, such that the feedback signal generated by the inverter circuit 21 is feedback to the output signal V1 through the first resistor portion 22 and the second resistor portion 24. That is, if the resistance of the first resistor portion 22 is set to R1 and the resistance of the second resistor portion 24 is set to R2, the feedback resistance will be R1+R2 in the case where the amplitude of the input signal VIN is less than the specific value. In addition, in the receiving circuit 1 of the embodiment, the first switch unit 23 is turned on when the amplitude of the input signal VIN is greater than or equal to the specific value, such that the feedback signal generated by the inverter circuit 21 is feedback to the output signal V1 through the first resistor portion 22 and the first switch unit 23. Therefore, the feedback resistance will be approximately R1, as the ON-state resistance of the first switch unit 23 is negligible when the amplitude of the input signal VIN is above the specific value.

In other words, in the receiving circuit 1 of the present embodiment, the feedback resistance becomes smaller (i.e., the amplitude of the feedback signal applied to the output signal V1 of the amplifier 10 becomes larger) when the amplitude of the input signal VIN is greater than or equal to the specific value (a value to turn on the first switch unit 23). Therefore, the amplitude of the output signal V1 of the amplifier 10 can be reduced. As shown in FIG. 2B, even if the pulse width of the input signal VIN (the pulse width of the input signal VIN at the high level shown in FIG. 2B) becomes shorter, the state of the output signal V1 will transition after the voltage of the output signal V1 reaches the saturation voltage (VREF−A2 (0<A2<A1) shown in FIG. 2B). A1 denotes the maximum amplitude and A2 denotes the amplitude which is less than A1 and greater than 0. In this case, the pulse width of the output signal V1 at the low level (L level) becomes wider as compared with the comparison example in FIG. 2A. Therefore, the input signal VIN at the high level can be appropriately detected by the receiving circuit 1.

As described above, according to the receiving circuit 1, the semiconductor memory device, and the control method thereof, the amplitude of the output signal V1 of the amplifier 10 can be reduced even when the amplitude of the input signal VIN is greater than or equal to the specific value. Therefore, the receiving circuit 1 can operate with this small amplitude of the output signal V1. Thus, even in the case where the amplitude of the input signal VIN is large and the pulse width is narrow, the logic level of the input signal VIN still can be appropriately detected by the receiving circuit 1.

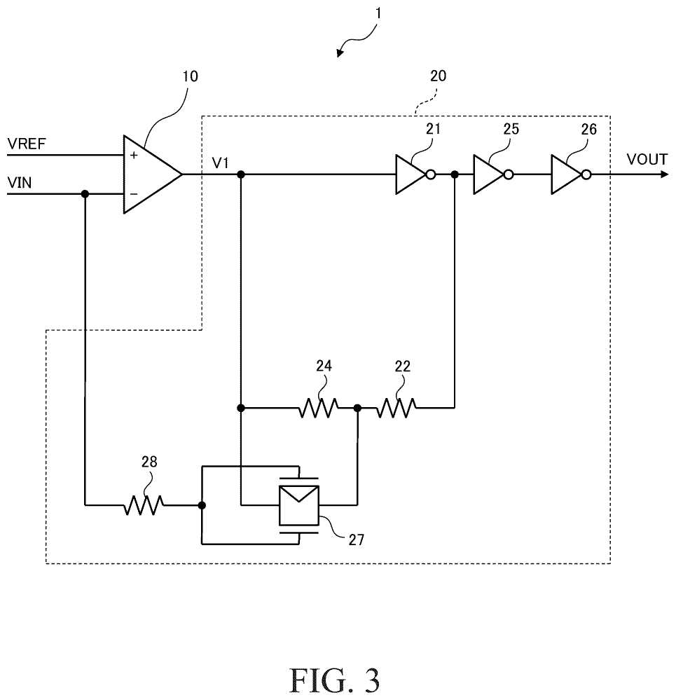

FIG. 3 shows an example of the configuration of a receiving circuit of a first alternative embodiment in the present invention. In the first alternative embodiment, the control unit 20 of the receiving circuit 1 includes a second switch unit 27 and a third resistor portion 28, in place of the first switch unit 23, which is different from the embodiment described above. In addition, the “switch circuit” of the present invention may be the first switch unit 23, the second switch unit 27, or a combination thereof.

One end of the second switch unit 27 is connected to the other end of the first resistor portion 22, and the other end of the second switch unit 27 is connected to the output of the amplifier 10. In addition, one end of the third resistor portion 28 is connected to the input signal VIN, and the other end of the third resistor portion 28 is connected to the second switch unit 27. The second resistor portion 24 is connected in parallel with the second switch unit 27 between the other end of the first resistor portion 22 and the output of the amplifier 10.

In addition, the second switch unit 27 is configured to be turned on when the amplitude of the input signal VIN is greater than or equal to the specific value. In the embodiment, the second switch unit 27 includes a transfer transistor, and gate terminals of the P-channel type MOSFET and the N-channel type MOSFET of the transfer transistor receive the input signal VIN through the third resistor portion 28. Further, in the embodiment, the N-channel type MOSFET of the transfer transistor is turned on when the amplitude of the signal with a logic value of “1” (high side) of the other end of the third resistor portion 28 is greater than or equal to the specific value. The P-channel type MOSFET of the transfer transistor is turned on when the amplitude of the signal with a logic value of “0” (low side) of the other end of the third resistor portion 28 is greater than or equal to the specific value. Therefore, regardless of whether the logic value of the signal of the other end of the third resistor portion 28 is “1” or “0”, the second switch unit 27 is turned on when the amplitude of the signal is greater than or equal to the specific value. Further, the second switch unit 27 may be composed of other circuits other than the transfer transistor. Hereby, the control unit 20 may provide a feedback resistance according to the input signal VIN. The feedback resistance (R1) provided by the control unit 20 when the amplitude of the input signal VIN is greater than or equal to the specific value is smaller than the feedback resistance (R1+R2) provided by the control unit 20 when the amplitude of the input signal VIN is less than the specific value. Furthermore, the resistance of the second switch unit 27 when the second switch unit 27 is turned on is smaller than the resistance of the second resistor portion 24.

In the embodiment of FIG. 1, the first switch unit 23 is directly controlled by the input signal VIN. Therefore, the first switch unit 23 may be capable of operating before the output signal V1 is output by the amplifier 10. On the other hand, in the alternative embodiment, the input signal VIN is input to the second switch unit 27 through the third resistor portion 28. Therefore, for example, when the resistance of the third resistor portion 28 is larger, the time at which the second switch unit 27 is turned on (i.e., the time at which the amplitude of the output signal V1 becomes smaller) is more delayed. Thus, for example, the amplitude of the output signal V1 can be appropriately reduced (i.e., control the time at which the feedback resistance is reduced) by adjusting the resistance of the third resistor portion 28 in consideration of the response time of the amplifier 10.

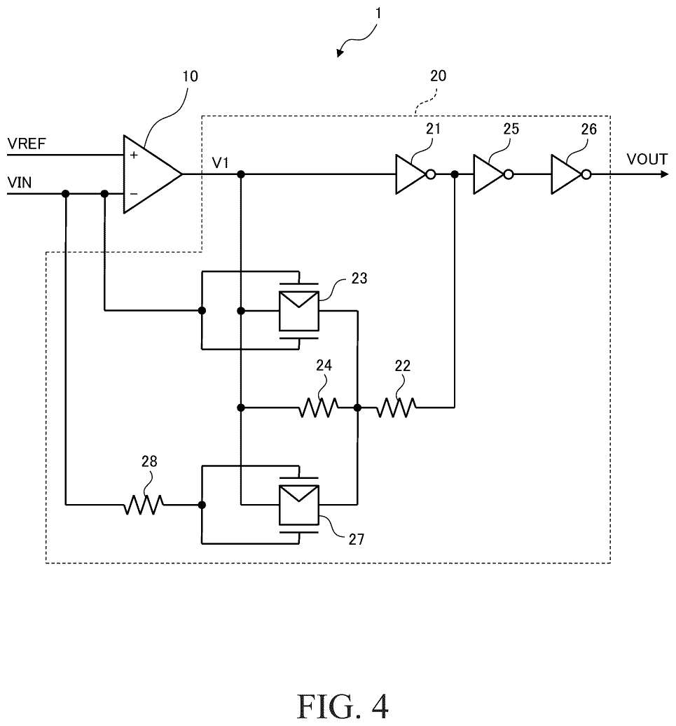

FIG. 4 shows an example of the configuration of a receiving circuit of a second alternative embodiment in the present invention. In the second alternative embodiment, the control unit 20 of the receiving circuit 1 has a composition combining the above embodiments.

In the second alternative embodiment, compared to the above embodiments, the period during which at least one of the first switch unit 23 and the second switch unit 27 is turned on is extended (i.e., the period during which the amplitude of the output signal V1 is reduced is longer). Thus, the receiving circuit 1 can operate with the small-amplitude output signal V1 over a longer period of time.

The embodiments described above are illustrated for the purpose of facilitating the understanding of the present invention and are not intended to limit the present invention. Accordingly, the various elements disclosed in the embodiments described above include all design variations and equivalents that fall within the technical scope of the present invention.

For example, in the embodiments described above, the input signal VIN (e.g., a command signal, an address signal, etc.) and the reference signal VREF are input to the amplifier 10, but the present invention is not limited thereto. For example, a clock signal (input signal) and a complementary signal of the clock signal may also be input to the amplifier 10. In this case, as in the above embodiments, the logic level of the clock signal may be appropriately detected. Further, other signals having a complementary relationship may also be input to the amplifier 10 in addition to the clock signal. Furthermore, the data signal may also be input to the amplifier 10 as the input signal VIN.

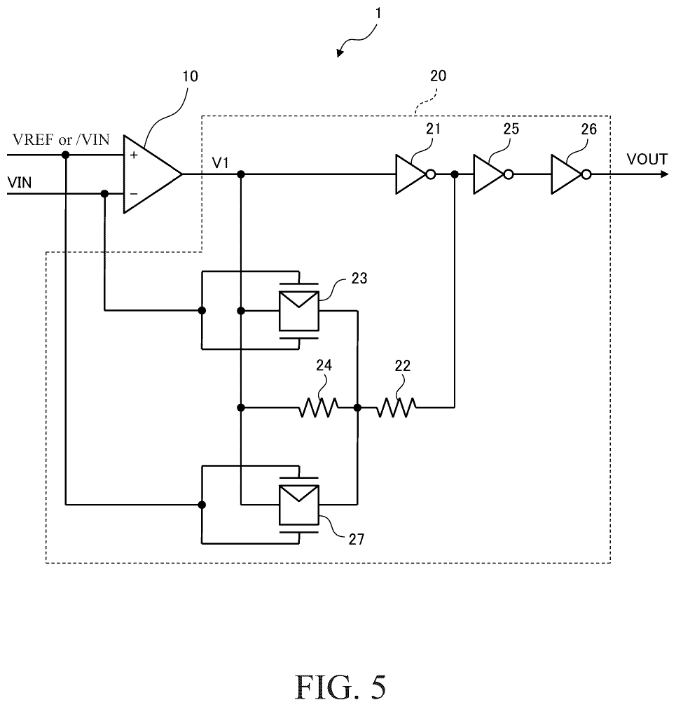

FIG. 5 shows an example of the configuration of a receiving circuit of a third alternative embodiment in the present invention. In the third alternative embodiment, the second input terminal (the “+” terminal) of the amplifier 10 may receive a complementary signal/VIN of the input signal VIN or the reference signal VREF, which is different from the above embodiments. In addition, in the third alternative embodiment, the second switch unit 27 is configured to include a transfer transistor as in the first and second alternative embodiments described above. However, the reference signal VREF or the complementary signal/VIN is input to gate terminals of the P-channel-type MOSFET of the transfer transistor and the N-channel-type MOSFET of the transfer transistor, which is different from the first and second alternative embodiments described above. That is, in the third alternative embodiment, the second switch unit 27 is turned on when the difference between the voltage of the reference signal VREF and a specific reference voltage (e.g., VDDQ/2) is greater than or equal to the specific value as described above, or when the amplitude of the complementary signal/VIN is greater than or equal to the specific value.

In the third alternative embodiment, the second switch unit 27 is configured to be turned on when the difference between the voltage of the reference signal VREF and the specific reference voltage (e.g., VDDQ/2) is greater than or equal to the specific value. Therefore, for example, when noise is applied to the reference signal VREF, causing the difference between the voltage of the reference signal VREF and the reference voltage (e.g., VDDQ/2) to increase, the voltage of the feedback signal output from the inverter circuit 21 may become large. In this way, the operation point of the input signal VIN can be prevented from being close to the power supply (e.g., VDDQ/VSSQ) side. In addition, in the third alternative embodiment, the second switch unit 27 is configured to turn on when the amplitude of the complementary signal/VIN is greater than or equal to the specific value so that the input capacity between the input signal VIN and the complementary signal/VIN can be consistent. In this way, the common mode noise can be effectively reduced.

In addition, the case in which the semiconductor memory device is a DRAM has been illustrated in the above embodiments, but the present invention is not limited thereto. For example, the semiconductor memory device may be a Static Random Access Memory (SRAM), a pseudo-Static Random Access Memory (pSRAM), a flash memory, or other semiconductor memory devices.

In addition, the configurations of the amplifier 10 and the control unit 20 shown in FIGS. 1 and FIGS. 3 to 5 are only examples, and may be suitably varied and used in known configurations or other various configurations.

What is claimed is:

1. A receiving circuit, comprising:
an amplifier including an output terminal and a plurality of input terminals, wherein the amplifier is configured to receive an input signal through one of the input terminals and amplify the input signal to generate an output signal at the output terminal; and
a control unit configured to receive the output signal and provide a feedback resistance based on the input signal, wherein the feedback resistance provided by the control unit when an amplitude of the input signal is greater or equal to a specific value is smaller than the feedback resistance provided by the control unit when the amplitude of the input signal is less than the specific value.

2. The receiving circuit according to claim 1, wherein the control unit is configured to reduce an amplitude of the output signal of the amplifier to a saturation voltage and invert the output signal after reaching the saturation voltage when the amplitude of the input signal is greater or equal to the specific value.

3. The receiving circuit according to claim 1, wherein the control unit is further configured to invert the output signal to generate a feedback signal coupled to the output terminal of the amplifier, and increase the amplitude of the feedback signal when the amplitude of the input signal is greater or equal to the specific value, such that the amplitude of the output signal of the amplifier is reduced.

4. The receiving circuit according to claim 1, wherein the control unit comprises:
an inverter circuit receiving the output signal;
a first resistor portion including one end connected to the output of the inverter circuit;
a switch circuit including one end connected to the other end of the first resistor portion, and the other end of the switch circuit connected to the output terminal of the amplifier, wherein the switch circuit is turned on when the amplitude of the input signal is greater or equal to the specific value; and
a second resistor portion connected in parallel with the switch circuit between the other end of the first resistor portion and the output terminal of the amplifier.

5. The receiving circuit according to claim 4, wherein the switch circuit comprises a transfer transistor, and the control unit further comprises one or more other inverter circuits connected in series to the output of the inverter circuit.

6. The receiving circuit according to claim 4, wherein the control unit further comprises:
a third resistor portion connected at one end to the input signal and at the other end to the switch circuit,
wherein the switch circuit is turned on when an amplitude of a signal at the other end of the third resistor portion is greater or equal to the specific value.

7. The receiving circuit according to claim 6, wherein the switch circuit comprises a first switch unit and a second switch unit, a gate terminal of the first switch unit receives the input signal, and a gate terminal of the second switch unit receives the signal passing through the third resistor portion.

8. The receiving circuit according to claim 4, wherein the plurality of input terminals of the amplifier receives the input signal and a reference signal, and the switch circuit comprises a first switch unit and a second switch unit, a gate terminal of the first switch unit receives the input signal, and a gate terminal of the second switch unit receives the reference signal, and the second switch unit is turned on when a voltage difference between a voltage of the reference signal and a specific reference voltage is greater or equal to the specific value.

9. The receiving circuit according to claim 8, wherein the voltage of the reference signal is half of the input/output voltage.

10. The receiving circuit according to claim 4, wherein the plurality of input terminals of the amplifier receives the input signal and a complementary signal of the input signal, and the switch circuit comprises a first switch unit and a second switch unit, a gate terminal of the first switch unit receives the input signal, and a gate terminal of the second switch unit receives the complementary signal, and the second switch unit is turned on when an amplitude of the complementary signal is greater or equal to the specific value.

11. The receiving circuit according to claim 1, wherein the input signal is an address signal or a command signal.

12. The receiving circuit according to claim 1, wherein the control unit is configured to, when the input signal has a narrow pulse width, control a pulse width of the output signal when the amplitude of the input signal is greater or equal to the specific value to be not less than the pulse width of the output signal when the amplitude of the input signal is less than the specific value.

13. A control method for a receiving circuit, comprising:
receiving and amplifying an input signal by an amplifier to generate an output signal; and
providing a feedback resistance by a control unit based on the input signal, wherein the feedback resistance provided by the control unit when an amplitude of the input signal is greater or equal to a specific value is smaller than the feedback resistance provided by the control unit when the amplitude of the input signal is less than the specific value.

14. The control method for the receiving circuit according to claim 13, wherein when the amplitude of the input signal is greater or equal to the specific value, the control unit reduces an amplitude of the output signal of the amplifier to a saturation voltage and inverts the output signal after reaching the saturation voltage.

15. The control method for the receiving circuit according to claim 13, further comprising:
inverting the output signal to generate a feedback signal coupled to the output terminal of the amplifier; and
increasing an amplitude of the feedback signal when the amplitude of the input signal is greater or equal to the specific value, such that the amplitude of the output signal of the amplifier is reduced.

16. The control method for the receiving circuit according to claim 13, further comprising:
receiving a reference signal by the amplifier, and the feedback resistance provided by the control unit when a voltage difference between a voltage of the reference signal and a specific reference voltage is greater or equal to the specific value is smaller than the feedback resistance provided by the control unit when the voltage difference is less than the specific value.

17. The control method for the receiving circuit according to claim 13, further comprising:
receiving a complementary signal of the input signal by the amplifier, wherein the feedback resistance provided by the control unit when an amplitude of the complementary signal is greater or equal to the specific value is smaller than the feedback resistance provided by the control unit when the amplitude of the complementary signal is less than the specific value.
